(19) United States
(12) Patent Application Publication
(10) Pub. No.: US 2011/0031461 A1
(43) Pub. Date: Feb. 10, 2011

(54) PHASE CHANGE MEMORY DEVICE

(75) Inventors: Myung-Jin KANG, Suwon (KR); Yong-Ho HA, Hwasung-city (KR); Doo-Hwan PARK, Seoul (KR); Jeong-Hee PARK, Hwasung-city (KR); Hee-Ju SHIN, Yongin-city (KR)

Correspondence Address: LEE & MORSE, P.C., 3141 FAIRVIEW PARK DRIVE, SUITE 500, FALLS CHURCH, VA, 22042, US

(73) Assignee: SAMSUNG ELECTRONICS CO., LTD., Suwon-si (KR)

(21) Appl. No.: 12/910,672

(22) Filed: Oct. 22, 2010

Related U.S. Application Data
(62) Division of application No. 12/073,210, filed on Mar. 3, 2008.

(30) Foreign Application Priority Data
Aug. 1, 2007 (KR) 10-2007-0077510

(51) Int. Cl. H01L 45/00

(52) U.S. Cl. 257/3; 257/E45.002

(57) ABSTRACT

A method of fabricating a phase change memory device includes forming an opening in a first layer, forming a phase change material in the opening and on the first layer, heating the phase change material to a first temperature that is sufficient to reflow the phase change material in the opening, wherein the first temperature is less than a melting point of the phase change material, and, after heating the phase change material to the first temperature, patterning the phase change material to define a phase change element in the opening.

### CROSS REFERENCE TO RELATED APPLICATION

This is a divisional application based on pending application Ser. No. 12/073,210, filed Mar. 3, 2008, the entire contents of which is hereby incorporated by reference.

### BACKGROUND OF THE INVENTION

1. Field of the Invention

Embodiments relate to a phase change memory device and method of fabricating the same.

2. Description of the Related Art

Continuing development of memory devices is directed to the formation increasingly dense memory structures. Phase change memory devices, e.g., phase change random access memory (PRAM) devices, may offer significant advantages in terms of density, and may be useful as non-volatile memory devices. Continuing development of phase change memory devices, however, requires advances in design and fabrication techniques in order to increase the density and reliability of such devices.

### SUMMARY OF THE INVENTION

Embodiments are therefore directed to a phase change memory device and method of fabricating the same, which substantially overcome one or more of the problems due to the limitations and disadvantages of the related art.

It is therefore a feature of an embodiment to provide a method of fabricating a phase change memory device in which a phase change material is subjected to a reflow process.

It is therefore another feature of an embodiment to provide a method of fabricating a phase change memory device in which voids in a phase change material are reduced or eliminated by reflowing the phase change material.

It is therefore another feature of an embodiment to provide a phase change memory device in which a phase change element is in contact with a wetting material.

At least one of the above and other features and advantages may be realized by providing a method of fabricating a phase change memory device, including forming an opening in a first layer, forming a phase change material in the opening and on the first layer, heating the phase change material to a first temperature that is sufficient to reflow the phase change material in the opening, wherein the first temperature is less than a melting point of the phase change material, and after heating the phase change material to the first temperature, patterning the phase change material to define a phase change element in the opening.

The first layer may exhibit wetting of the phase change material during reflow, and the phase change material may be formed directly on the first layer. The method may further include forming a wetting layer on the first layer before depositing the phase change material, the wetting layer contacting the phase change material. The wetting layer may be formed on sidewalls of the opening, such that the wetting layer separates the phase change material in the opening from the first layer. The wetting layer may be formed only on sidewalls of the opening.

The wetting layer may include one or more of Ti, TiC, TiN, TiO, SiC, SiN, Ge, GeC, GeN, GeO, C, CN, TiSi, TiSiC, TiSiN, TiSiO, TiAl, TiAlC, TiAlN, TiAlO, TiW, TiWC, TiWN, TiWO, Ta, TaC, TaN, TaO, Cr, CrC, CrN, CrO, Pt, PtC, PtN, PtO, Ir, IrC, IrN, or IrO. The wetting layer may include one or more of TiN or TiO, and the phase change material may include GST.

The method may further include forming at least one layer on the phase change material prior to heating the phase change material to the first temperature. Forming the at least one layer may include forming a capping layer that includes one or more of a nitride or an oxide. Forming the at least one layer may include forming an electrode material layer. Forming the at least one layer may include forming a capping layer on the electrode material layer, such that the electrode material layer is between the phase change material layer and the capping layer.

The first temperature may be at least as high as a crystallization temperature of the phase change material. The crystallization temperature of the phase change material may correspond to a temperature to which the phase change material is heated when converting it to a crystalline phase in a phase change memory device. The phase change material may be GST, the first temperature may be less than 632° C., and the first temperature may be about 450° C. or more.

At least one of the above and other features and advantages may be realized by providing a phase change memory device, including a first insulating layer having an opening therein, a phase change element in the opening, the phase change element being changed between amorphous and crystalline states through self-heating, and first and second electrodes contacting bottom and top surfaces, respectively, of the phase change element, wherein a wetting material for a phase change material of the phase change element is in contact with the phase change element.

The wetting material for the phase change material may be part of the first insulating layer. A wetting layer may be disposed on sidewalls of the opening between the first insulating layer and the phase change element, and the wetting material for the phase change material may be part of the wetting layer.

A contact area between the phase change element and the first electrode may be confined to a lower half of the phase change element. A contact area between the phase change element and the first electrode may be confined to a bottom surface of the phase change element. The wetting material may define a lateral extent of the phase change element in the opening.

### BRIEF DESCRIPTION OF THE DRAWINGS

The above and other features and advantages will become more apparent to those of ordinary skill in the art by describing in detail exemplary embodiments thereof with reference to the attached drawings, in which:

FIG. 1 illustrates an example phase change memory device according to a first embodiment;

FIGS. 2a-2f illustrate cross-sectional views of stages in a method of fabricating the phase change memory device illustrated in FIG. 1;

FIGS. 3a-3c illustrate cross-sectional views of stages in a method of fabricating a phase change memory device according to a second embodiment;

FIGS. 4a-4c illustrate cross-sectional views of stages in a method of fabricating a phase change memory device according to a third embodiment;

FIGS. 5a-5d illustrate cross-sectional views of stages in a method of fabricating a phase change memory device according to a fourth embodiment;

FIGS. 6a-6d illustrate cross-sectional views of stages in a method of fabricating a phase change memory device according to a fifth embodiment; and

FIG. 7 illustrates results of a simulation of void formation in openings of varying aspect ratios.

### DETAILED DESCRIPTION OF THE INVENTION

Korean Patent Application No. 10-2007-0077510, filed on Aug. 1, 2007, in the Korean Intellectual Property Office, and entitled: “Phase Change Memory Devices and Methods of forming the Same,” is incorporated by reference herein in its entirety.

Embodiments will now be described more fully hereinafter with reference to the accompanying drawings; however, they should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Where an element is described as being connected to a second element, the element may be directly connected to second element, or may be indirectly connected to second element via one or more other elements. Further, where an element is described as being connected to a second element, it will be understood that the elements may be electrically connected, e.g., in the case of transistors, capacitors, power supplies, nodes, etc. In the figures, the dimensions of regions may be exaggerated and elements may be omitted for clarity of illustration. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B and, C together, whereas the expression “either A, B, or C” means one of A alone, B alone, and C alone, and does not mean any of both A and B together; both A and C together; both B and C together; and all three of A, B and C together.

Embodiments provide a phase change memory device and a method of fabricating the same in which a phase change material is deposited in an opening, e.g., a high aspect ratio opening, and the phase change material is subsequently subjected to a reflow process. Materials that exhibit wetting of the phase change material may be used in combination with the reflow process. The reflow process may include heating to a temperature that is less than a melting temperature of the phase change material.

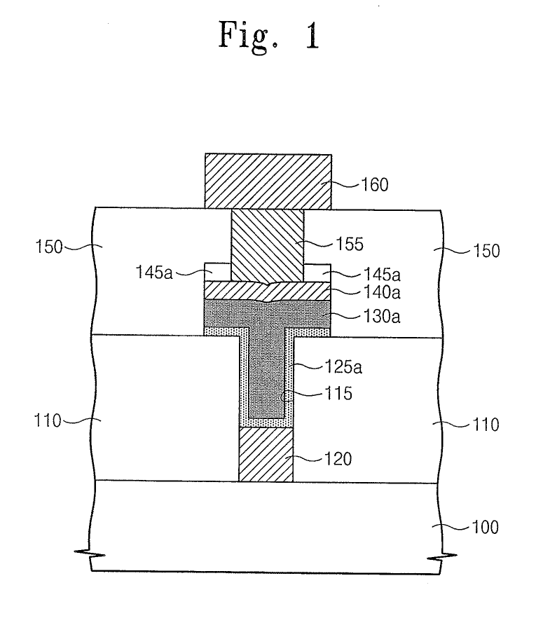

FIG. 1 illustrates an example cell of a phase change memory device according to a first embodiment. Referring to FIG. 1, a substrate 100 may have a first insulating interlayer 110 thereon. The first interlayer insulating layer 110 may have an opening 115 therein, and a lower electrode 120 may be disposed at a bottom portion of the opening 115. A wetting layer pattern 125a may be on the lower electrode 120, on sidewalls of the opening 115, and on the first insulating interlayer 110. A phase change material pattern 130a may be on the wetting layer pattern 125a in the opening 115 and on the wetting layer pattern 125a on the first insulating interlayer 110. An upper electrode 140a may be on the phase change material pattern 130a, and a capping layer pattern 145a may be on the upper electrode 140a. A conductive plug 155a may be on the upper electrode 140a. The conductive plug 155a may extend through the capping layer pattern 145a and a second insulating interlayer 150, and may be in contact with both the upper electrode 140a and an overlying metal line 160. The phase change memory device according to embodiments may employ diodes, transistors, etc., to select a given memory cell. A change in phase of the phase change material pattern 130a, i.e., a change between amorphous and crystalline phases, may be generated through self-heating, i.e., Joule heating, as a result of current passing between the upper and lower electrodes 140a and 120 through the phase change material pattern 130a. In an implementation, the upper and lower electrodes 140a and 120 may provide a low-resistance electrical path to the phase change material pattern 130a, such that resistance heating is not generated in the upper and lower electrodes 140a and 120.

The opening 115 may have a relatively narrow width and/or a high aspect ratio, i.e., a high ratio of height:width. Thus, the phase change material pattern 130a in the opening 115 may similarly have a narrow width and/or a high aspect ratio. The width of the phase change material pattern 130a may be less than that of the opening 115 due to the presence of the wetting layer pattern 125a. The aspect ratio of the phase change material pattern 130a may be the same as or different from the aspect ratio of the opening 115. The area of the phase change memory device that is occupied by the phase change material pattern 130a may be small, allowing the density, i.e., the number of phase change material patterns 130a per unit area, to be increased. Further, the narrow width and/or high aspect ratio may allow the density to be increased while maintaining a predetermined distance, i.e., separation, between adjacent phase change material patterns 130a. Accordingly, a phase change memory cell may be operated with little or no thermal disturbance of an adjacent phase change memory cell, e.g., such as may be caused by heating during a data write operation.

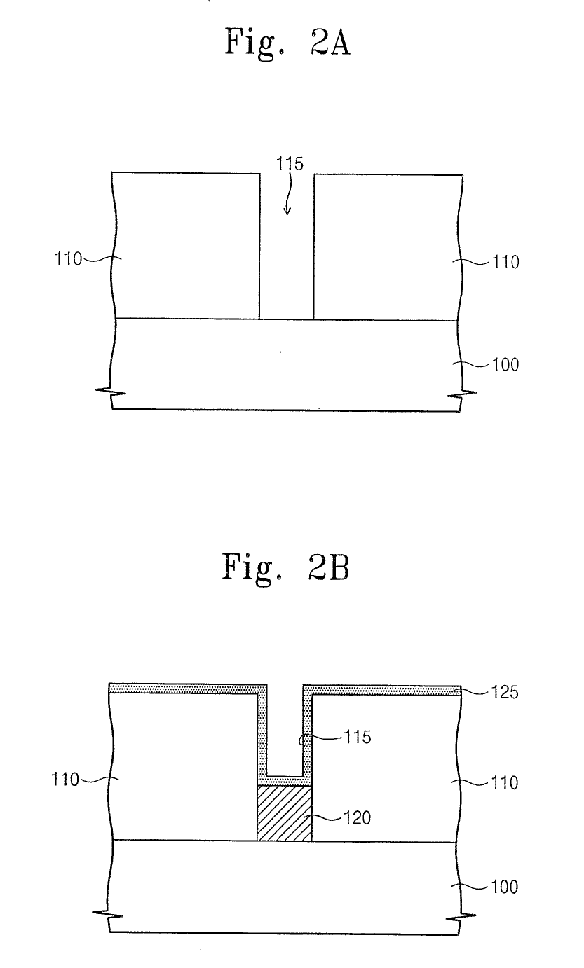

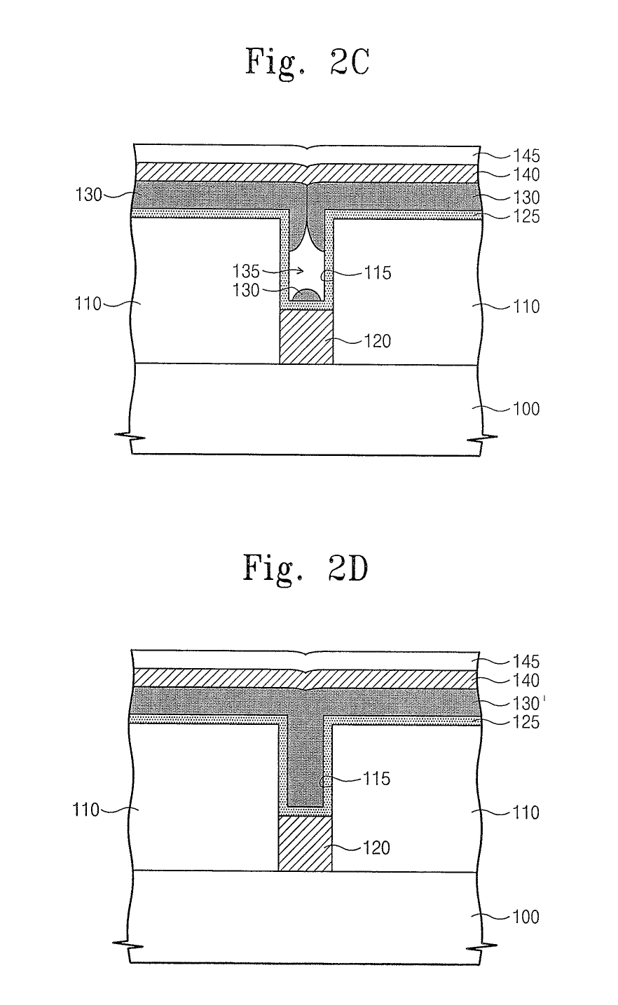

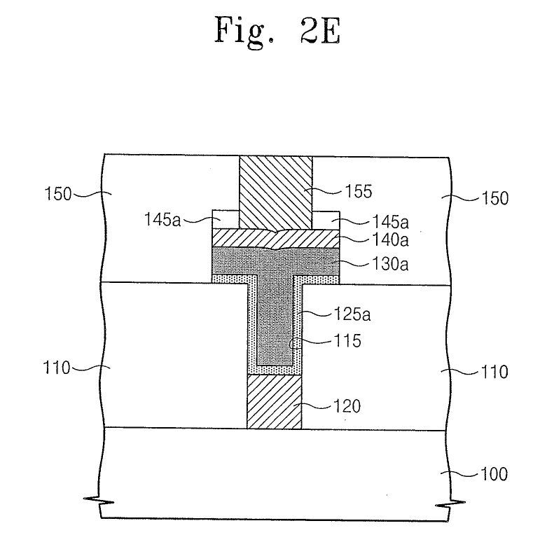

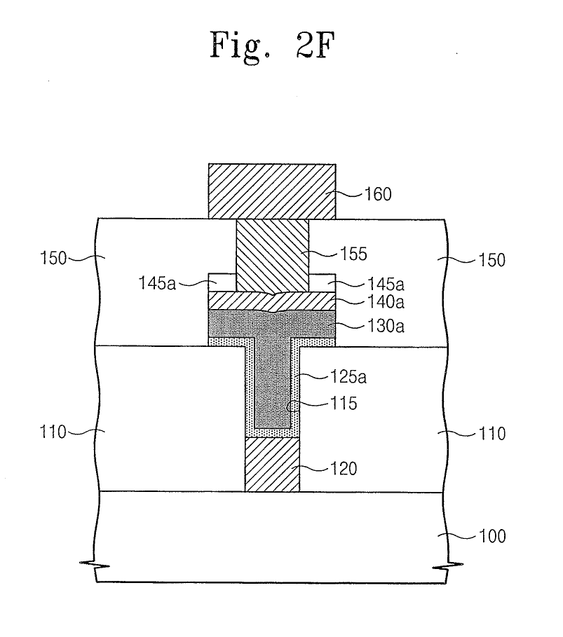

Details of a method of fabricating the example memory device illustrated in FIG. 1 will now be described with reference to FIGS. 2a-2f. Referring to FIG. 2a, the first insulating interlayer 110 may be formed on the substrate 100. The substrate 100 may be any substrate material that is suitable for use in a phase change memory device, and may include active devices, passive devices, etc. The opening 115 may be formed in the first insulating interlayer 110 using, e.g., a general lithographic process including masking, exposing, and developing a photoresist layer (not shown), followed by etching the first insulating interlayer 110 to form the opening 115 therein using the patterned photoresist layer as a mask. The photoresist layer may then be removed.

Referring to FIG. 2b, a lower electrode material may then be deposited in the opening 115 to form the lower electrode 120. Forming the lower electrode 120 may include, e.g., depositing a lower electrode material layer (not shown) on the first insulating interlayer 110 and in the opening 115, and planarizing the lower electrode material layer using chemical mechanical polishing (CMP). An additional process may be employed to recess the lower electrode material layer in the opening 115 to form the lower electrode 120. The lower electrode 120 may be electrically connected to underlying wiring or other conductive features (not shown).

A wetting layer 125 may be formed on the lower electrode 120, on sidewalls of the opening 115, and/or on the upper surface of the first insulating interlayer 110. The wetting layer 125 may enhance the effects of the reflow process applied to a subsequently-formed phase change material pattern, details of which are described below. The wetting layer 125 may be formed using, e.g., a conformal deposition process such as chemical vapor deposition (CVD) process or an atomic layer deposition (ALD) process. The wetting layer 125 may have a different chemical composition than the first insulating interlayer 110. The wetting layer 125 may include, e.g., one or more materials such as Ti, TiC, TiN, TiO, SiC, SiN, Ge, GeC, GeN, GeO, C, CN, TiSi, TiSiC, TiSiN, TiSiO, TiAl, TiAlC, TiAlN, TiAlO, TiW, TiWC, TiWN, TiWO, Ta, TaC, TaN, TaO, Cr, CrC, CrN, CrO, Pt, PtC, PtN, PtO, Ir, IrC, IrN, or IrO. A particular wetting material or combination of materials may be selected based on the particular material(s) used for a phase change material layer 130 from which the phase change material pattern 130a is subsequently formed. As a particular example, the wetting layer 125 may be formed using a combination of TiN and TiO, and the phase change material layer 130 may be formed of Ge₂Sb₂Te₅ (GST). The wetting layer 125 may have a thickness of about 100 Å or less, or may be processed, e.g., etched back, to have a thickness of about 100 Å or less on the lower electrode 120, so as to enable an electric current to flow from the lower electrode 120 through the phase change material pattern 130a in the completed memory device.

Referring to FIG. 2c, the phase change material layer 130 may be formed on the wetting layer 125. An upper electrode layer 140 and a capping layer 145, e.g., an oxide or nitride capping layer, may be formed on the phase change material layer 130. The material used for the phase change material layer 130 may include, e.g., one or more chalcogenides such as Ge—Sb—Te, As—Sb—Te, As—Ge—Sb—Te, Sn—Sb—Te, Ag—In—Sb—Te, or In—Sb—Te. The phase change material layer 130 may be formed using, e.g., a physical vapor deposition (PVD) process such as sputtering.

As illustrated in FIG. 2c, PVD may form the phase change material layer 130 on the upper surface of the wetting layer 125. PVD may also deposit the phase change material layer 130 in an upper portion of the opening 115 and/or at the bottom of the opening 115. However, depending on the materials employed, the PVD conditions, and the width and aspect ratio of the opening 115, a void 135 may also remain in the opening 115, the void 135 not being filled by the phase change material layer 130. Conventionally, an approach to avoiding the formation of voids 135 would be to design the memory cell such that the opening 115 is wide and/or has a lower aspect ratio. For example, the aspect ratio of the opening may be set to be less than one, such that the width of the opening 115 is greater than its height. Even with an aspect ratio of less than one, however, voids 115 may still be generated.

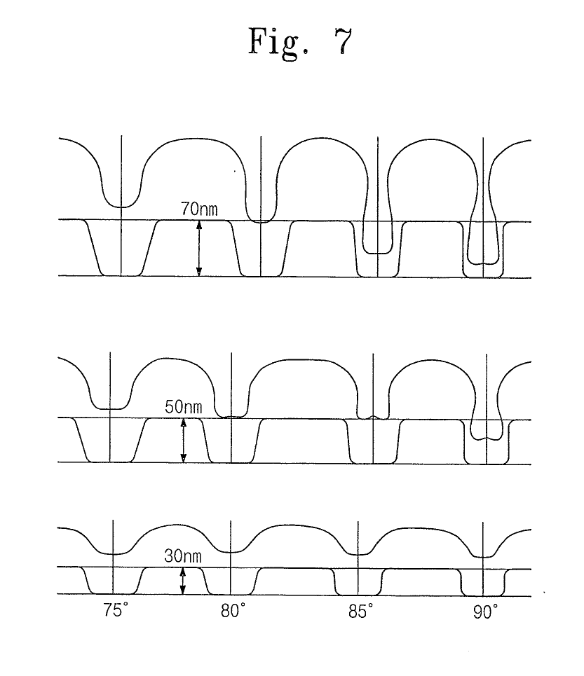

FIG. 7 illustrates results of a simulation of void formation in openings of varying aspect ratios. Referring to FIG. 7, the simulation shows the results of sputtering at various angles (75°, 80°, 85°, and 90°) to form phase change material layers on substrates having openings 50 nm in diameter, the substrates having a height of 70 nm (upper diagram in FIG. 7), 50 nm (middle diagram), or 30 nm (lower diagram). As can be seen from the simulation, even where the aspect ratio is unity, i.e., 1:1, some openings may not be completely filled by the phase change material that is sputtered on the substrate. See, e.g., the middle diagram (50 nm thick substrate) at the right-most example (90° sputtering angle). In an actual device, void formation may be detected using, e.g., scanning electron microscopy (SEM).

It will be appreciated that a design in which the width of the opening 115 is large and/or the aspect ratio of the opening 115 is low, which may be required in order to avoid the formation of voids 135, may result in a low density of memory cells per unit area, may result in thermal disturbances due to memory cells being too closely spaced, etc. In contrast, as described herein, a reflow process may be performed to reflow the phase change material layer 130, such that the voids 135 are reduced in size or completely eliminated from the completed phase change memory device, while enabling the use of narrow or high aspect ratio openings 115. For example, the reflow process may enable the use of openings 115 having an aspect ratio of three (3:1) with a width of about 50 nm, which, without the reflow process, would be likely to generate voids 135.

As described above, the reflow process may allow narrow openings 115 to be used, which may allow the density of memory cells to be increased by reducing the area occupied by each cell, and/or allow a greater separation to be maintained between adjacent cells. Further, tall and narrow openings 115 may be used, i.e., openings having a high aspect ratio, which may allow a high density of memory cells while also providing a longer electrical path through the phase change material pattern 130a formed in the opening 115. The longer electrical path may result in a increased overall resistance of the phase change material pattern 130a when it is in the amorphous state, which may provide a greater change in resistance when switching between the amorphous state and the crystalline state, thereby making it easier to distinguish between these two states, i.e., making it easier to distinguish between a logic ‘1’ and a logic ‘0’.

Referring to FIG. 2d, the reflow process may be performed to cause the phase change material in the opening 115 to reflow, forming a reflowed phase change material layer 130′. The reflowed phase change material layer 130′ may partially or completely fill the opening 115 with the phase change material. The upper electrode layer 140 and the capping layer 145 may help prevent vaporization of the phase change material during reflow. One or more of the reflowed phase change material layer 130′, the upper electrode layer 140 and the capping layer 145 may exhibit a non-planar surface, as shown in FIG. 2d.

During the reflow process, the phase change material layer 130 may be heated to a temperature that is less than a melting temperature of the phase change material and higher than a crystallization temperature of the phase change material. The crystallization temperature is the temperature above which the phase change material pattern 130a is heated when changing the phase change material pattern to the crystalline phase during programming of the phase change memory device. The crystalline phase may have a lower resistivity than an amorphous phase, which may provide a resistance differential corresponding to data stored in the phase change memory device.

As a particular example, where the phase change material layer 130 is formed from GST, the melting temperature of the phase change material layer 130 may be about 632° C., and the reflow process may heat the phase change material layer 130 to a temperature of 450° C., i.e., about 182° C. less than the melting temperature, and may maintain the 450° C. temperature for about 30 minutes. In the following additional examples, the reflow process may heat a phase change material layer 130 formed from the listed material to a temperature less than the corresponding melting temperature Tm: GeSb₄Te₇ (Tm=607° C.), GeSb₂Te₄ (Tm=614° C.), Ge₄Sb₂Te₇ (Tm=634° C.), Ge₈Sb₂Te₁₁ (Tm=690° C.), In₄₉Sb₂₃Te₂₈, (Tm=620° C.), As₂₄Sb₁₆Te₆₀ (Tm=377° C.) Se₂₀Sb₂₀Te₆₀ (Tm=396° C.), and Ag₅In₅Sb₆₀Te₃₀ (Tm=573° C.).

As noted above, the wetting layer 125 may enhance the effects of the reflow process. In particular, the wetting layer 125 may enable the phase change material layer 130 to flow and fill in the voids 135 during the reflow process. The wetting layer 125 may enable the phase change material to wet the walls of the opening 135 in the same way that a liquid forms a concave meniscus with a glass container. In contrast, upon reflow, if no wetting layer 125 is present, the phase change material may exhibit a convex upper surface that is similar to a convex meniscus formed by mercury in a glass container. Additionally, the wetting layer 125 may enhance the distance over which the phase change material moves during reflow. For example, reflow without the wetting layer 125 may result in little or no movement of the phase change material. Reflow with the wetting layer 125 may result in movement of the phase change material that ranges from about 10 nm to significantly greater amounts.

Referring to FIG. 2e, following the reflow process, the wetting layer 120, the phase change material layer 130, the upper electrode layer 140, and the capping layer 145 may be patterned, e.g., using a general lithography process, to form the wetting layer pattern 120a, the phase change material pattern 130a, the upper electrode 140a, and the capping layer pattern 145a. The second insulating interlayer 150 may then be formed on the first insulating interlayer 110, and on the stacked wetting layer pattern 120a, phase change material pattern 130a, upper electrode 140a, and capping layer pattern 145a. The conductive plug 155 may be formed to penetrate the second insulating layer 150 and the capping layer pattern 145a so as to contact the upper electrode 140a. The conductive plug 155 may be formed by, e.g., using a general lithography process to pattern the second insulating interlayer 150 and the capping layer pattern 145a, applying a conductive layer on the second insulating interlayer 150, and removing the conductive layer from the second insulating interlayer 150, e.g., with a CMP process, so as to leave the conductive plug 155 extending through the second insulating interlayer 150. Referring to FIG. 2f, the metal line 160 may then be formed to contact the conductive plug 155.

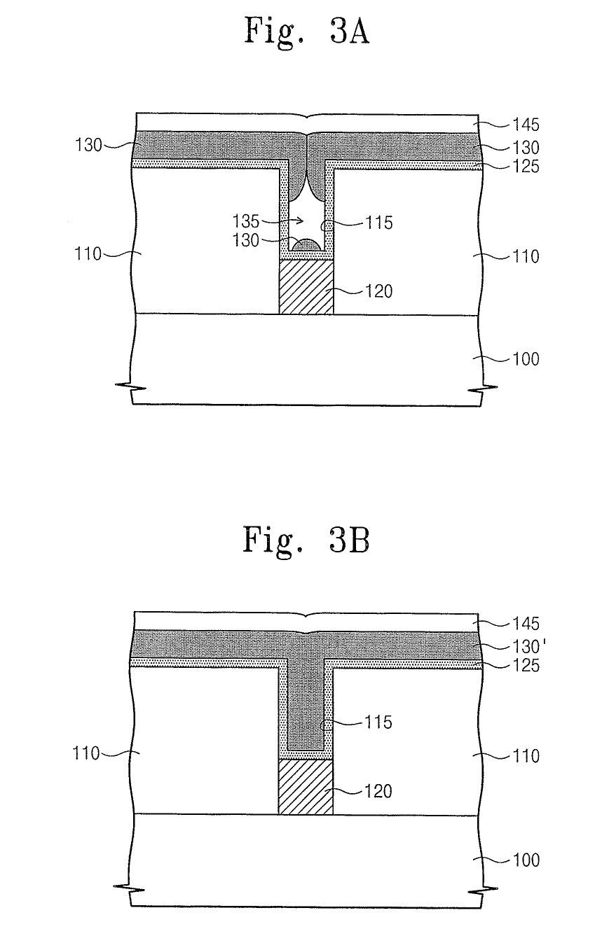

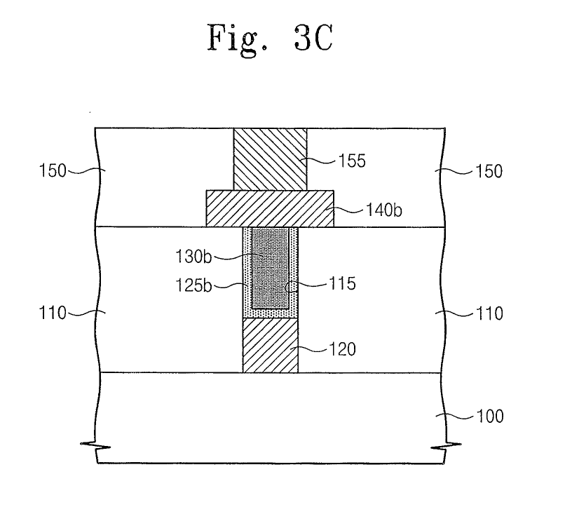

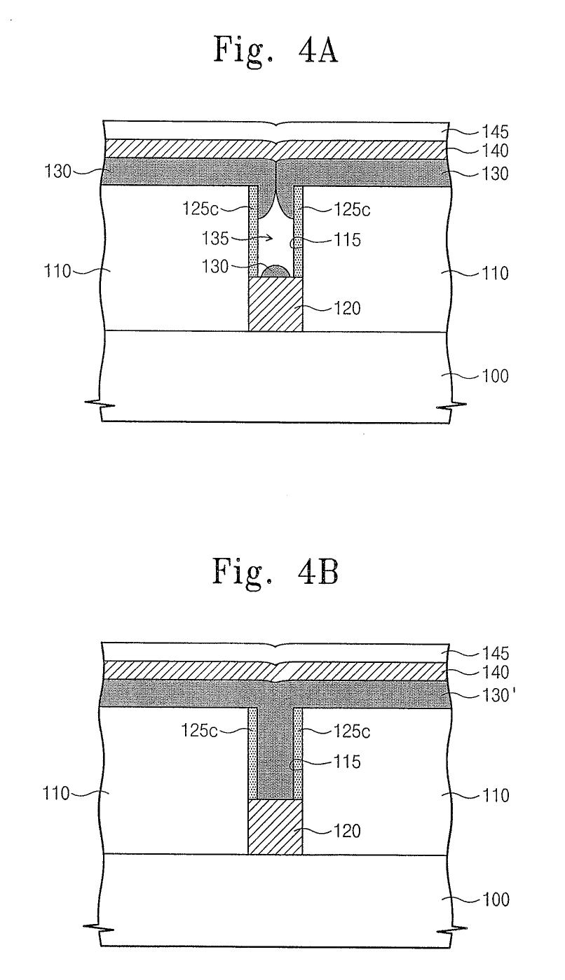

FIGS. 3a-3c illustrate cross-sectional views of stages in a method of fabricating a phase change memory device according to a second embodiment. Referring to FIG. 3a, the phase change material layer 130 may be formed on the wetting layer 125, e.g., using PVD, as described above in connection with FIG. 2c. Again, the reflowed phase change material layer 130 may partially or completely fill the opening 115, i.e., voids 135 may be formed.

The capping layer 145 may be formed on the phase change material layer 130. The upper electrode layer 140, however, may not be formed at this stage. In particular, the capping layer 145 may be formed directly on the phase change material layer 130. Referring to FIG. 3b, the phase change material layer 130 may be reflowed with the capping layer 145 thereon. Thus, as compared with the embodiment described above in connection with FIG. 2c, the upper electrode layer 140 may not be present during the reflow process.

The presence of the upper electrode layer 140 during the reflow process may be helpful to prevent vaporization of the phase change material layer 130 during reflow and, depending on the material used for the phase change material layer 130, it may be desirable to have formed both the upper electrode layer 140 and the capping layer 145 prior to reflow. Further, depending on the material used for the upper electrode layer 140, the capping layer 145 may be omitted or formed after reflow (not shown).

Referring to FIG. 3c, the capping layer 145, the reflowed phase change material layer 130′, and the wetting layer 125 may then be selectively removed, e.g., using a CMP process, so as to form a wetting layer pattern 125b and a phase change material pattern 130b in the opening 115. Etching back the wetting layer 125 to expose the upper first insulating interlayer 110 may allow the overall height of the completed phase change memory cell to be reduced. Subsequently, an upper electrode 140b may be formed on the first insulating interlayer 110, the wetting layer pattern 125b, and the phase change material pattern 130b. The second insulating interlayer 150 and the conductive plug 155 may be formed on the upper electrode 140b, e.g., in the same manner as described above in connection with FIG. 2e, and metal wiring lines (not shown) may be formed thereon e.g., in the same manner as described above in connection with FIG. 2f.

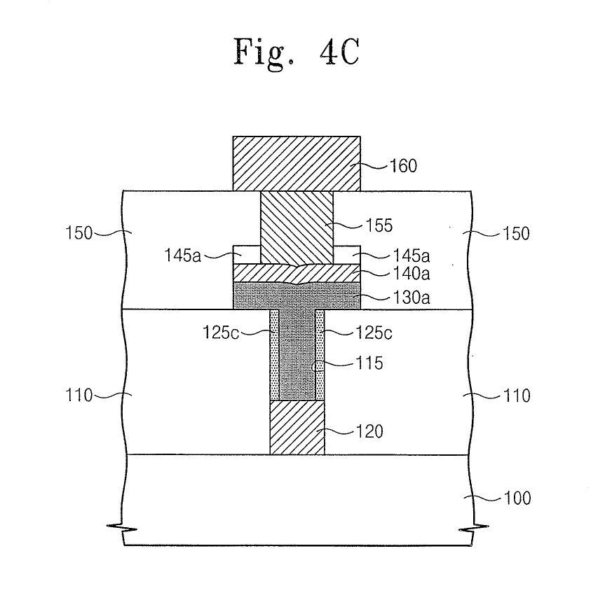

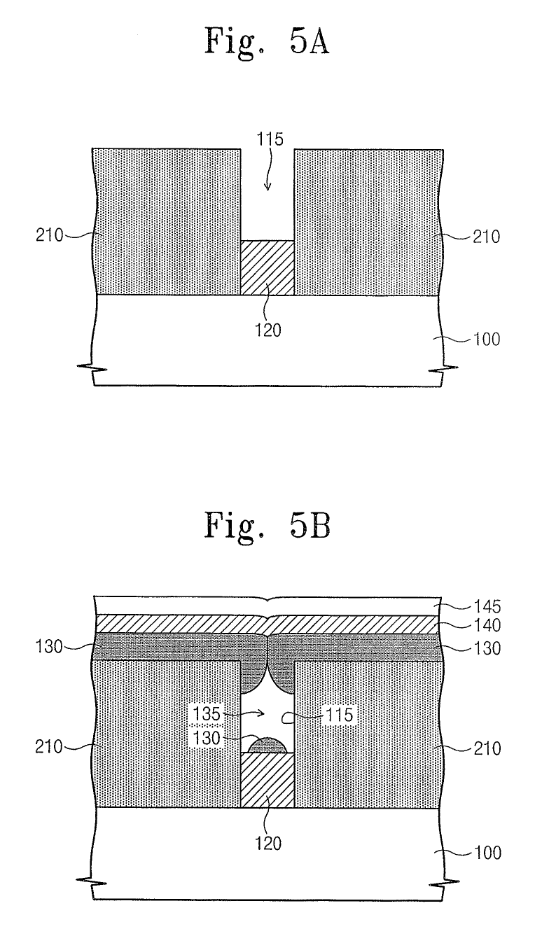

FIGS. 4a-4c illustrate cross-sectional view of stages in a method of fabricating a phase change memory device according to a third embodiment. Referring to FIG. 4a, a wetting layer pattern 125c may be formed on sidewalls of the opening 115. The wetting layer pattern 125c may expose the upper surface of the first insulating interlayer 110 and may expose the lower electrode 120 in the opening 115. For example, the wetting layer 125 may be formed as described above in connection with FIG. 2b, after which CMP and/or another etch process may be employed to selectively remove the wetting layer 125 from the upper surface of the first insulating interlayer 110 and the lower electrode 120 in the opening 115.

Removing the wetting layer 125 from the upper surface of the first insulating interlayer 110 may allow the overall height of the completed phase change memory cell to be reduced, as described above. Further, removing the wetting layer 125 from the lower electrode 120 may enhance electrical conductivity between the lower electrode 120 and the phase change material pattern 130a formed thereon. Further, since the wetting layer 125 is selectively removed, thicker layers and/or different materials may be used for the wetting layer 125.

Referring to FIGS. 4a and 4b, the phase change material layer 130, the upper electrode layer 140, and the capping layer 145 may then be formed, after which the reflow process may be used to fill voids 135 that may exist in the openings 115, e.g., in the same manner as described above in connection with FIGS. 2c and 2d. Referring to FIG. 4c, subsequent operations forming the phase change material pattern 130a and the remaining features of the phase change memory cell may be performed e.g., in the same manner as described above in connection with FIGS. 2e and 2f.

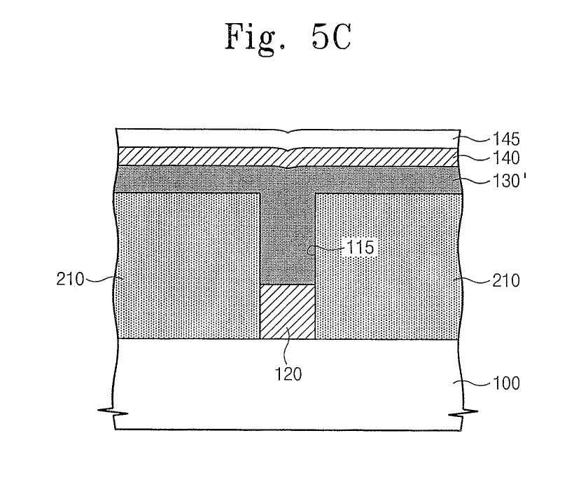

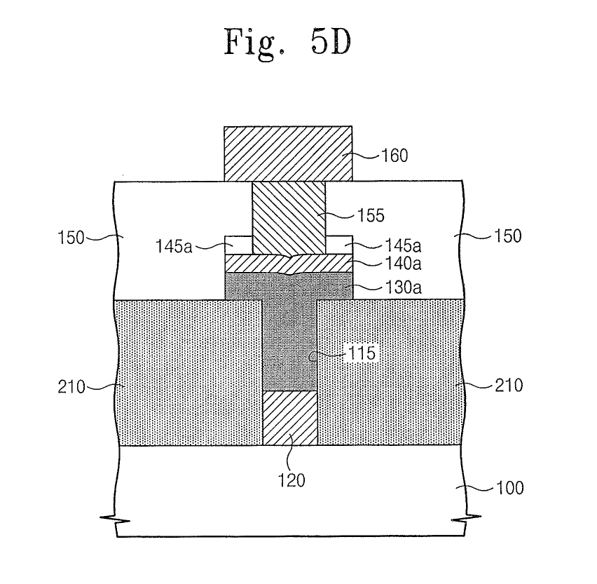

FIGS. 5a-5d illustrate cross-sectional views of stages in a method of fabricating a phase change memory device according to a fourth embodiment. Referring to FIG. 5a, a first insulating interlayer 210 may be formed using an insulating material that exhibits wetting properties with respect to the subsequently-formed phase change material layer 130. Accordingly, the phase change material layer 130 may be formed directly on the first insulating interlayer 210, as illustrated in FIG. 5b.

By avoiding the use of the wetting layer 125 described in connection with the first through third embodiments, an entire volume of the opening 115 may be filled with the phase change material pattern 130a. Further, avoiding the use of the wetting layer 125 may provide more flexibility with respect to the process employed to deposit the phase change material layer 130, e.g., since the absence of the wetting layer 125 in the opening 115 effectively provides a wider aperture that may be easier to fill. Additionally, avoiding the use of the wetting layer 125 may provide more flexibility with respect to the materials used for the phase change material layer 130, e.g., by allowing the use of phase change materials that have relatively poorer PVD characteristics, and/or allow the width of the opening 115 to be further reduced.

Referring to FIG. 5b, the upper electrode layer 140 and the capping layer 145 may be formed on the phase change material layer 130, as described above in connection with FIG. 2c. Referring to FIG. 5c, the phase change material layer 130 may be reflowed to fill any voids 135 that may exist in the opening 115, as described above in connection with FIG. 2d. Referring to FIG. 5d, the phase change material layer 130, the upper electrode layer 140, and the capping layer 145 may be patterned to form a phase change material pattern 130d, the upper electrode 140a, and the capping layer pattern 145a, after which the second insulating interlayer 150, the conductive plug 155 and the metal line 160 may be formed, e.g., in the same manner as described above in connection with FIGS. 2e and 2f. As illustrated in FIG. 5d, the phase change material pattern 130a may be in the opening 115 and on the upper surface of the first insulating interlayer 210. The width and/or aspect ratio of the phase change material pattern 130a may be the same as that of the opening 115.

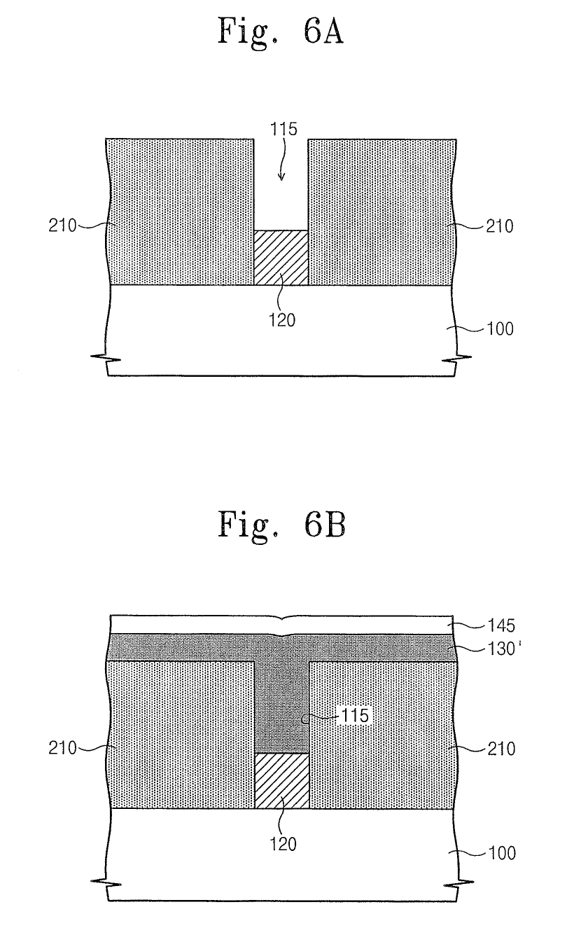

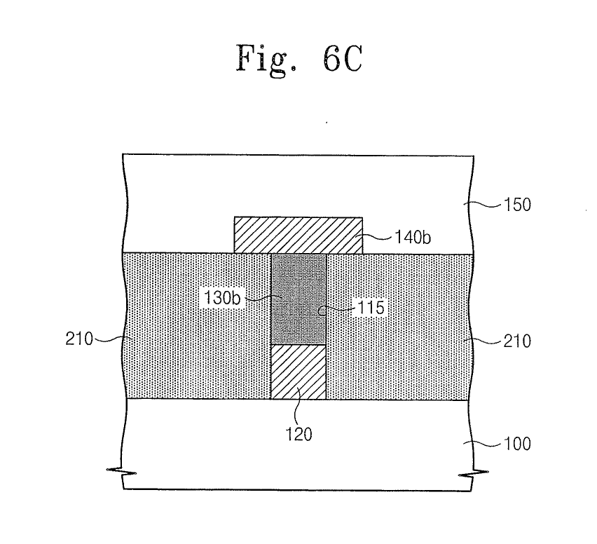

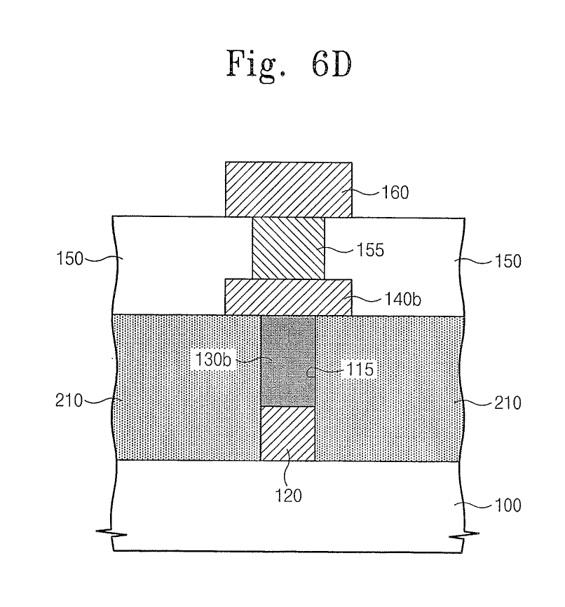

FIGS. 6a-6d illustrate cross-sectional views of stages in a method of fabricating a phase change memory device according to a fifth embodiment. Referring to FIG. 6a, the first insulating interlayer 210 may be formed using an insulating material that exhibits wetting properties with respect to the subsequently-formed phase change material layer 130. Accordingly, the phase change material layer 130 may be formed directly on the first insulating interlayer 210, as illustrated in FIG. 6b.

As illustrated in FIG. 6b, the capping layer 145 may be formed directly on the phase change material layer 130, after which the phase change material layer 130 may be reflowed. Referring to FIG. 6c, the capping layer 145 and the phase change material layer 130 may be selectively removed to form the phase change material pattern 130b, and the upper electrode layer 140 may be applied and patterned to form the upper electrode 140b, e.g., in the same manner as described above in connection with FIG. 3c. The second insulating interlayer 150 and the conductive plug 155 may then be formed, e.g., in the same manner as described above in connection with FIG. 3c. The metal line 160 may then be formed to contact the conductive plug 155. As illustrated in FIG. 6d, the phase change material pattern 130b may completely fill the opening 115, and the overall height of the phase change cell may be minimized by forming the upper electrode 140b on the first insulating interlayer 210, i.e., without the phase change material pattern 130b being interposed between the upper surface of the first insulating interlayer 210 and the upper electrode 140b.

Example embodiments have been disclosed herein, and although specific terms are employed, they are used and are to be interpreted in a generic and descriptive sense only and not for purpose of limitation. For example, an example embodiment has been described wherein a phase change material layer is reflowed to reduce or eliminate voids, after which the layer is patterned. It will be appreciated, however, that the phase change material layer may be patterned and then reflowed. Accordingly, it will be understood by those of ordinary skill in the art that various changes in form and details may be made without departing from the spirit and scope of the present invention as set forth in the following claims.

1.-14. (canceled)

15. A phase change memory device, comprising:
a first insulating layer having an opening therein;
a phase change element in the opening, the phase change element being changed between amorphous and crystalline states through self-heating; and
first and second electrodes contacting bottom and top surfaces, respectively, of the phase change element, wherein a wetting material for a phase change material of the phase change element is in contact with the phase change element.

16. The device as claimed in claim 15, wherein the wetting material for the phase change material is part of the first insulating layer.

17. The device as claimed in claim 15, wherein:
a wetting layer is disposed on sidewalls of the opening between the first insulating layer and the phase change element, and
the wetting material for the phase change material is part of the wetting layer.

18. The device as claimed in claim 15, wherein a contact area between the phase change element and the first electrode is confined to a lower half of the phase change element.

19. The device as claimed in claim 15, wherein a contact area between the phase change element and the first electrode is confined to a bottom surface of the phase change element.

20. The device as claimed in claim 15, wherein the wetting material defines a lateral extent of the phase change element in the opening.
